(19) United States
(12) Patent Application Publication
(10) Pub. No.: US 2008/0079159 A1
(43) Pub. Date: Apr. 3, 2008

(54) Focused stress relief using reinforcing elements

(75) Inventors: Vikas Gupta, Dallas, TX (US); Gregory Eric Howard, Dallas, TX (US)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 11/542,336

(22) Filed: Oct. 2, 2006

(51) Int. Cl. H01L 23/52; H01L 21/4763

(52) U.S. Cl. 257/758; 438/622; 438/926

(57) ABSTRACT

In a method and system for relieving stress induced within a dielectric layer of a semiconductor device (100), areas in the dielectric layer (236, 238, 242) where the stress exceeds a threshold are identified. The areas, which are in parallel alignment with electrical interconnects such as conductive bumps (130), include a selected number of outer rows of the conductive bumps (130) having a high stress level. Within the identified areas where the stress exceeds the threshold, patterned zones (250) having an adjustable zone density are provided by adding reinforcing elements (240) to relieve the stress below the threshold.

### BACKGROUND

The present invention is related in general to the field of electronic systems and semiconductor devices and more specifically to tools and methods for improving structural stress bearing capability of an insulating layer having a low constant (k) dielectric material to withstand thermomechanical and/or mechanical stresses.

The shrinking dimensions of the integrated circuit has resulted in decreasing the spacing between electrical interconnects, such as metal lines. This has increased capacitance between conductive elements, thereby causing loss of speed, delays, and increased cross-talk. It is well known that low k dielectric materials having a dielectric constant k of less than 4 may be used to replace traditional dielectric material such as silicon oxide to lower the capacitance and improve the speed. It is also well known that the lower the dielectric k of the insulating material the lower is its structural and/or mechanical strength.

However, many traditional tools and methods for improving the mechanical strength of the low k dielectric material, especially in an inter layer dielectric (ILD), may be inadequate to withstand high thermomechanical and/or mechanical stress (may also be simply referred to as stress) conditions encountered during a test (e.g., multi-probe), an assembly process (wafer dice, die attach, wire bond, and underfill), and/or during customer use. For example, during a temperature cycling process the temperature may vary from 150 degrees Celsius to −55 degrees Celsius. Difference between the coefficients of thermal expansion (CTE) of various components within the integrated circuit (IC) generates stresses, which tend to fatigue the joints and the bumps, resulting in cracks, and may eventually lead to a failure of the assembly. Some of the traditional methods for improving the mechanical strength of the low k dielectric material may also be costly, time consuming, and ineffective in being integrated into existing IC fabrication processes.

### SUMMARY

The applicants recognize an existing need for an improved method and system for focused strengthening of the structure of low k dielectric materials used in an inter layer dielectric (ILD) to reduce stress induced during the manufacture and testing of semiconductor devices; and the need for a method for manufacturing the low k dielectric material having an improved stress bearing capability that may be easily and cost effectively integrated into existing IC fabrication processes, absent the disadvantages found in the prior techniques discussed above.

The foregoing need is addressed by the teachings of the present disclosure, which relates to a system and method for improving the stress bearing capability of low k dielectric material incorporated in integrated circuits. According to one embodiment, in a method and system for relieving stress induced within a dielectric layer of a semiconductor device, areas in the dielectric layer where the stress exceeds a threshold are identified. The areas, which are in parallel alignment with electrical interconnects such as conductive bumps, include a selected number of outer rows of the conductive bumps having a high stress level. Within the identified areas where the stress exceeds the threshold, patterned zones having an adjustable zone density are provided by adding reinforcing elements to relieve the stress below the threshold.

Several advantages are achieved by the method and system according to the illustrative embodiments presented herein. The embodiments advantageously provide for selectively adding reinforcing elements in an inter layer dielectric (ILD) of an IC to improve the stress bearing capability. Increasing density of the reinforcing elements advantageously results in reducing the stress in the ILD layer compared to an ILD layer without the reinforcing elements. Thus, the focused approach of reinforcement provides targeted stress relief without substantially compromising insulation properties of the ILD. This advantageously enables semiconductor manufacturing facilities to improve production rates, quality and reliability.

### BRIEF DESCRIPTION OF THE DRAWINGS

FIG. 1A illustrates a simplified and schematic cross section of a semiconductor device assembly;

FIG. 1B illustrates a top view of a semiconductor device assembly described with reference to FIG. 1A;

FIG. 2A illustrates a sectional view of a stack without reinforcing elements;

FIG. 2B is a top view of an inter layer dielectric (ILD) without reinforcing elements illustrating stress variation;

FIG. 2C is a top view illustrating position of the conductive bumps 130 that are likely to experience increased stress levels;

FIG. 2D illustrates a sectional view of a stack with reinforcing elements, according to an embodiment;

FIG. 2E is a top view of an ILD layer illustrating formation of a patterned zone of reinforcing elements, according to an embodiment;

FIG. 2F illustrates a patterned zone having a zone density of 6.5%, according to an embodiment;

FIG. 2G illustrates a patterned zone having a zone density of about 25%, according to an embodiment;

FIG. 3 shows a graphical representation illustrating variation in stress level as a function of density of reinforcing elements within a patterned zone; and

FIG. 4 is a flow chart illustrating a method for relieving stress induced within a dielectric layer of a semiconductor device, according to an embodiment.

### DETAILED DESCRIPTION

Novel features believed characteristic of the present disclosure are set forth in the appended claims. The disclosure itself, however, as well as a preferred mode of use, various objectives and advantages thereof, will best be understood by reference to the following detailed description of an illustrative embodiment when read in conjunction with the accompanying drawings. The functionality of various circuits, devices or components described herein may be implemented as hardware (including discrete components, integrated circuits and systems-on-a-chip ‘SoC’), firmware (including an application specific integrated circuit ‘ASIC’ and programmable chips) and software or a combination thereof, depending on the application requirements. Similarly, the functionality of various mechanical elements, members, and components, or a combination thereof for forming modules, sub-assemblies and assemblies assembled in accordance with a structure for an apparatus may be implemented using various materials and coupling techniques, depending on the application requirements.

Traditional tools and methods for strengthening low k dielectric materials may be inadequate to withstand high stress conditions encountered during the fabrication and testing of semiconductor devices. In addition, some of the traditional methods may be costly, time consuming, and ineffective in being integrated into existing integrated circuit fabrication processes. This problem may be addressed by an improved system and method for a focused strengthening of the structure of low k dielectric materials to reduce the induced stress. According to an embodiment, in an improved system and method for relieving stress induced within a dielectric layer of a semiconductor device, areas in the dielectric layer where the stress exceeds a threshold are identified. The areas, which are in parallel alignment with electrical interconnects such as conductive bumps, include a selected number of outer rows of the conductive bumps having a high stress level. Within the identified areas where the stress exceeds the threshold, patterned zones having an adjustable zone density are provided by adding reinforcing elements to relieve the stress below the threshold.

The following terminology may be useful in understanding the present disclosure. It is to be understood that the terminology described herein is for the purpose of description and should not be regarded as limiting.

Electrical Interconnect—A technique to provide electrical coupling between two electrical elements. The electrical interconnect uses conductive material such as metal (e.g., aluminum, copper, silver, gold, and similar others including alloys) to achieve the electrical interconnection. The interconnect, which is an essential part of any semiconductor device, may include conductive traces, conductive bumps, solder bumps, vias, metal planes, bond wires, metal lands, metal planes, bond wire areas, conductive pads, metal studs, and similar others.

Ball grid array (BGA)—A type of chip package type that enables direct mounting of the chip to a substrate or printed circuit board via solder balls or bumps. The solder balls or bumps are arranged in a grid-style array and found on the underside of the chip to make the electrical connection to the outside.

Flip Chip (FC)—A technique to surface mount a chip or die on to a substrate (or a board) by flipping and directly connecting the chip or die to the substrate without using traditional wire bonding technique. The direct connection is typically via solder balls or conductive bumps. The gap between the chip and the substrate is underfilled with a polymeric material. A FC package configuration includes at least one semiconductor chip or die mounted in an active surface-down manner over a substrate (or another semiconductor chip) electrically and mechanically coupled to the same by means of the conductive bumps.

Chip scale package (CSP)—A chip package in which the total package size is no more than 20% greater than the size of the die within.

Low k dielectric—A dielectric material having a constant k value of less than 4.0, preferably below 2.5. Low k dielectric materials may be formed from hybrids of organic and silicate materials, such as organosilicate glass (OSG).

Wirebond package—Wirebonding is an electrical interconnection technique that uses thin wires and a bonding agent such as a heat, pressure and ultrasound energy or a combination thereof. Well known semiconductor device packages that use wirebonding (referred to as a ‘wirebond package’) include ball grid array (single chip and multi-chip), ceramic and plastic quad flat packages, chip scale packages, and a chip on board (COB) package.

Mechanical or structural strength of a dielectric—The mechanical or structural strength of a dielectric is a property of the dielectric that enables it to resist deformation under load or stress. The mechanical or structural strength of the dielectric material is primarily determined by factors such as the density and porosity of the bulk material forming the dielectric. The strength of the dielectric may refer to its tensile strength, shear strength, cohesive and adhesive strength, and/or fracture toughness. Ultimate strength is the maximum stress level that the material can withstand without a failure. The ultimate strength may be classified into three main groups according to the applied stress type, e.g., ultimate tensile strength (UTS), ultimate compression strength, and ultimate shear strength. Tensile strength is measured in units of force per unit area, e.g., newtons per square meter (N/m²) or pascals (Pa), with prefixes as appropriate.

Reinforcing Elements—Conductive elements such as metal vias that are selectively added to a dielectric layer of a semiconductor device to specifically reinforce and improve the stress bearing capability of the dielectric layer. The reinforcing elements are positioned to absorb a large portion of the induced stress within the dielectric layer, thereby providing improved stress protection to the semiconductor device. Specifically, the reinforcing elements are intentionally added to relieve the stress below the threshold. The process to form the reinforcing elements is identical to the well-known process to form vias.

Zone Density—The zone density is an indicator of a ‘local’ density of a material within a selectable zone. The zone density is a ratio of a cross sectional area of the reinforcing elements included within the selectable zone to an area, e.g., cross sectional area, of the selectable zone. The zone density may also be computed as a ratio of a volume of metal contained within a volume of the selectable zone to the volume of the selectable zone. The zone density computed as a ratio of areas generally assumes a uniform distribution of the volume of the metal. In applications, where distribution of the metal volume is not uniform, e.g., conically shaped vias, volume based zone density computations may be more desirable compared to area based computations.

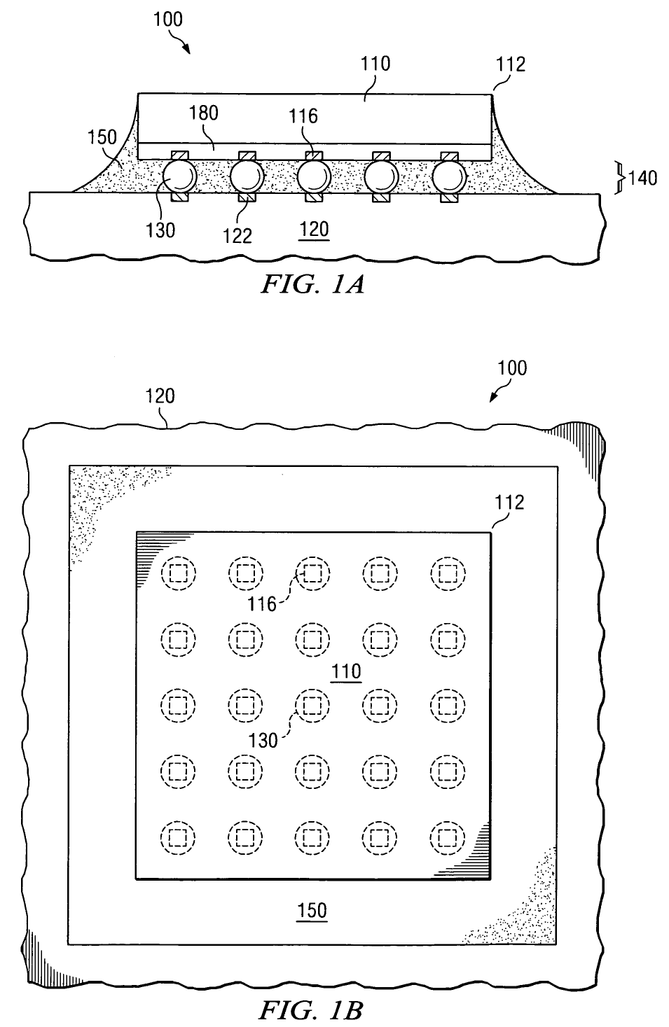

The present disclosure provides the tools and methods for focused strengthening of low k dielectric material by selectively adding reinforcing elements to high stress areas. Patterned zones having increased density due to the addition of the reinforcing elements are formed in the high stress areas of the dielectric layer. The addition of the reinforcing elements advantageously improves the stress bearing capability of the dielectric layer to withstand the stress induced during the assembly and testing process, as described with reference to FIGS. 1A, 1B, 2A, 2B, 2C, 2D, 2E, 2F, 2G and 3. While certain aspects of the present disclosure have been described in the context of FC mounting, those of ordinary skill in the art will appreciate that the processes disclosed are capable of being used for assembly of semiconductor devices using different types of mounting techniques including conventional mounts having other types of electrical interconnects such as bond wires. For example, in a FC the stress concentration in the back end of line (BEOL) is primarily under the conductive bumps, as the conductive bumps form the link between the die and the substrate. Similar induced stresses exist in wirebond packages when the bond pad is probed, during wire bonding process, and during temperature cycling. Additionally, although stresses generated within the chip are described as being both mechanical and thermomechanical, additional types of stresses may also be created due to various other types of loads.

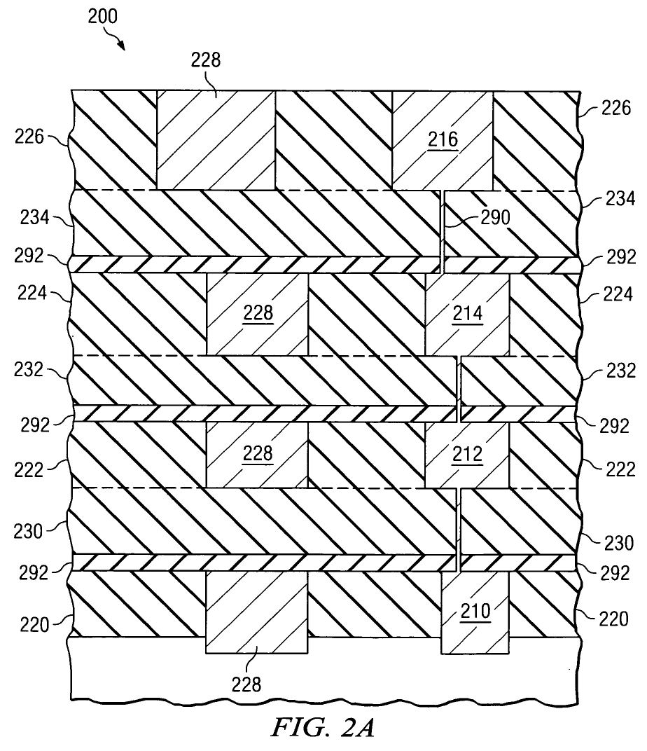

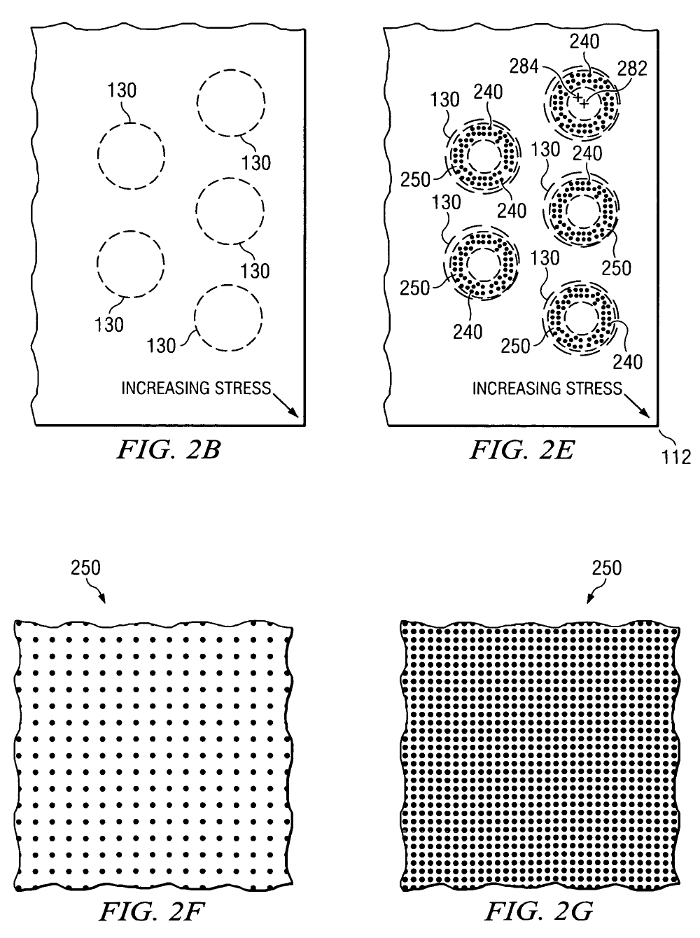

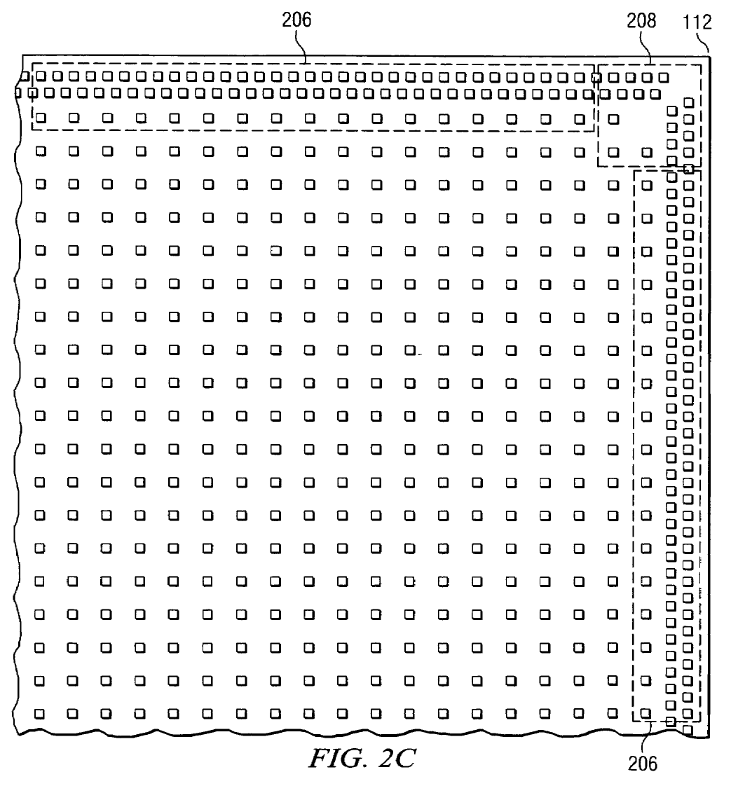

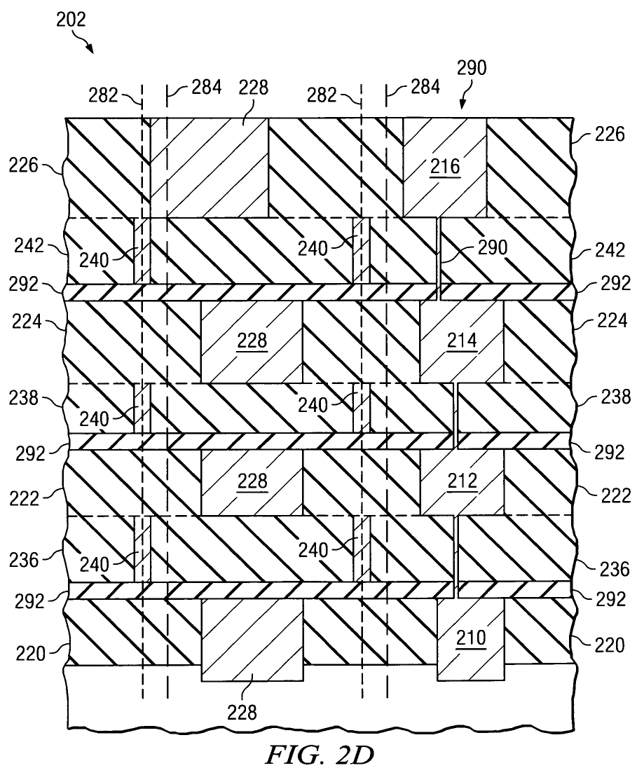

FIG. 1A illustrates a simplified and schematic cross section of a semiconductor device assembly 100. FIG. 1B illustrates a top view of the semiconductor device assembly 100 described with reference to FIG. 1A. Referring to FIGS. 1A and 1B, the semiconductor device assembly 100 is a flip chip assembly which includes a die (or an integrated circuit chip) 110, a stack 180 that includes a plurality of interconnect layers (also referred to as a back end of line ‘BEOL’ stack), the stack 180 being attached to a substrate (or a flexible film, or a board) 120 using electrical interconnects such as conductive bumps (also referred to as solder bumps, solder balls, pads, or simply as interconnects) 130. A gap 140 formed between the die 110 and the substrate 120 is filled with an underfill (or a polymeric material) 150. The die 110 is preferably formed of silicon. Although not shown the semiconductor device assembly 100 may include a lid cover for the die 110 that may protrude beyond a die corner 112, depending on packaging options. Additional details of the stack 180 are described with reference to FIGS. 2A, 2B, 2C and 2D.

A plurality of contact pads 116 are disposed on the stack 180. In an exemplary, non-depicted embodiment, the plurality of contact pads 116 may include 3 layers with the first layer being preferably made of aluminum, copper-doped aluminum, or copper or a combination thereof, a second layer made from a refractory metal such as titanium or tungsten, and a third layer made from a noble metal such as palladium, gold, or platinum.

The die 110 is mounted on the substrate 120 integral with interconnections and a plurality of terminal pads 122, yet spaced apart by the gap 140. The substrate 120 preferably includes a printed circuit board made of FR-4 or a glass-epoxy laminate, and the plurality of terminal pads 122 are preferably composed of solder-wettable copper. The die 110 is attached by reflowable solder bumps 130, which extend across the gap 140 and connect the plurality of contact pads 116 on the die 110 to a corresponding one of the plurality of terminal pads 122 on the substrate 120 both electrically and mechanically. Preferably, tin or a tin alloy (such as tin/indium, tin/bismuth, tin/lead) of a desirable melting temperature is chosen for the conductive bumps 130 to accomplish the reflow at a practical temperature. For silicon packages, a protective “solder mask” (not shown) may be made of a variety of insulating materials including polymers such as polyimide. Although the die 110 is shown to be mounted as a flip chip, other types of mounting such as upright with wire bonding are also contemplated. In a particular embodiment, the semiconductor device assembly 100 may be packaged as at least one of a chip scale package (CSP) and a ball grid array (BGA) package. In an exemplary, non-depicted embodiment, the semiconductor device assembly 100 may be packaged as a traditional wirebond package.

FIG. 2A illustrates a sectional view of a stack 200 without reinforcing elements. In a particular embodiment, the stack 200 is substantially the same as the stack 180 described with reference to FIGS. 1A and 1B. In the depicted embodiment, the stack 200 includes 4 layers of metallization (M1 210, M2 212, M3 214, and M4 216) to form the various interconnects such as a via 290 between the die 110 and the conductive bumps 130. Although only 4 layers of metallization are shown, it is understood that the number of layers of metallization (e.g., local. Intermediate, and global) included in the stack 200 may vary depending on the application. Each one of the plurality of interconnect layers, which may also be referred to as the ‘BEOL’ stack, may include an inter metal dielectric (IMD), a dielectric layer (ILD), and a barrier layer separating an adjacent interconnect layer. The IMD layers (e.g., layers with metal lines), may also be referred to as interconnect layers. In the illustration, each of the interconnect layers of the stack 200 is separated from an adjacent layer by at least one non-conductive or barrier layer 292. In a particular embodiment, layers M1 210, M2 212, M3 214, and M4 216 include a low k dielectric material. The stack 200 includes inter metal dielectric (IMD) layers such as IMD1 220, IMD2 222, IMD3 224, and IMD4 226 when the layer is composed of the low k dielectric material and an interconnect metal 228. The stack 200 includes inter layer dielectric (ILD) layers such as ILD2 230, ILD3 232, and ILD4 234 when the layer is primarily composed of the low k dielectric material disposed between the vias.

In the presence of an induced stress, the IMD layer may be exposed to a lower risk compared to the ILD layer, since the IMD layer has a higher metal density compared to the ILD layer. That is, due to the presence of the interconnect metal 228 in the IMD layer such as IMD1 220, IMD2 222, IMD3 224, and IMD4 226, the density and hence the stress bearing capability of this layer may be greater than the stress induced. However, a non-reinforced ILD layer such as ILD2 230, ILD3 232, and ILD4 234 may not have sufficient strength to withstand the stress induced. As such, the non-reinforced ILD layer may be subject to damage when the induced stress exceeds its strength. Thus, within one interconnect layer, the IMD layer may be better equipped to handle induced stress, whereas the non-reinforced ILD layer may be unable to handle the induced stress due to the difference in their respective densities.

In an embodiment, areas within the non-reinforced ILD layer where the stress exceeds a threshold are identified by using modeling and simulation tools, by conducting a stress test, or by a combination thereof. The threshold stress value for a selected area within an ILD layer is a particular stress value, which if exceeded may cause an undesirable change in the ILD layer. The threshold value is dependent on the materials selected to form the ILD layer, and may be determined by using well-known material properties, modeling and simulation tools, by conducting a stress test or by a combination thereof. Since the stress induced during processes such as die attach, propagates radially outward in three dimensions from the conductive bumps 130, the areas in the non-reinforced ILD layer that experience stress levels exceeding the threshold are radially aligned with the conductive bumps 130.

FIG. 2B is a top view illustrating variation in a level of the stress induced in the ILD layer such as ILD2 230, ILD3 232, and ILD4 234 without reinforcing elements. The modeling and simulation tools, and stress testing tools described earlier may be used to estimate induced stress levels at each one of the conductive bumps 130. The distribution of stress generally increases diagonally from the center of the die 110 to each one of the corners 112 of the die 110. Thus, areas of the ILD layer that are closer to the corners 112 of the die 110 and closer to the peripheral edge of the die 110 are likely to experience increased stress levels compared to the ILD layer located at the center of the die 110.

FIG. 2C is a top view illustrating position of the conductive bumps 130 that are likely to experience increased stress levels. In a particular embodiment, not all conductive bumps 130 may be selected for the focused or selective strengthening. Selection criteria for the focused strengthening include selecting each one of the conductive bumps 130 that has an induced stress level that is above the threshold. Conductive bumps 130 that are located in areas 206 at the periphery or perimeter of the die 110 and areas 208 near each one of the corners 112 of the die 110 are likely to experience the highest stress levels. In an embodiment, about 5-10% of the conductive bumps 130 may be desired to be reinforced. The stress level may decrease towards the center of the die 110. The stress distribution is applicable to all the ILD layers without reinforcing elements, such as ILD2 230, ILD3 232, and ILD4 234.

FIG. 2D illustrates a sectional view of a stack 202 with reinforcing elements 240, according to an embodiment. In a particular embodiment, the stack 202 is substantially the same as the stack 180 described with reference to FIGS. 1A and 1B. The stack 202 is also substantially similar to the stack 200 except for the ILD layer, which includes the reinforcing elements 240. In the depicted embodiment, the stack 202 includes 4 layers of metallization (M1 210, M2 212, M3 214, and M4 216) to form the various interconnects such as the via 290 between the die 110 and the conductive bumps 130. Although only 4 layers of metallization are shown, it is understood that the number of layers of metallization included in the stack 202 may vary depending on the application. Each of the interconnect layers of the stack 202 is separated from an adjacent layer by at least one non-conductive or barrier layer 292. In a particular embodiment, layers M1 210, M2 212, M3 214, and M4 216 include a low k dielectric material. The stack 202 includes inter metal dielectric (IMD) layers such as IMD1 220, IMD2 222, IMD3 224, and IMD4 226 which are composed of the low k dielectric material and the interconnect metal 228. The stack 202 also includes an ILD layer such as ILD2R 236, ILD3R 238, and ILD4R 242 with reinforcing elements 240. The ILD layer with reinforcing elements 240 is primarily composed of the low k dielectric material and the reinforcing elements 240. A reinforcing element vertical axis 282 of the reinforcing elements 240 is parallel in alignment but separate from a conductive bump vertical axis 284 of a corresponding conductive bump. In an embodiment, the process to form the reinforcing elements 240 is identical to the well-known process to form vias.

FIG. 2E is a top view of an ILD layer illustrating formation of a patterned zone 250 of the reinforcing elements 240, according to an embodiment. In the depicted embodiment, an area of the patterned zone 250 may vary to substantially cover the entire area, the higher stress areas of the conductive bumps 130, and/or a portion thereof. Although the patterned zone 250 is shown to have a cross sectional shape of an annular ring, the patterned zone 250 may also have other types of shapes such as a square, a circle, a crescent and similar others. The patterned zone 250 is parallel aligned with areas having a selected number of the conductive bumps 130, which experience the highest stress levels. Thus, a number of patterned zones formed in the dielectric layer corresponds to a number of electrical interconnects selected within the areas that experience the highest stress levels. The center of the patterned zone 250 is the reinforcing element vertical axis 282 and the center of the corresponding conductive bump is the conductive bump vertical axis 284. Areas experiencing the highest stress levels may include the area 208 located near each of the corners of the die 110, and the area 206 located at the periphery or perimeter of the die 110. The area 206 may be extended to include the outer 3 or 4 rows of the conductive bumps 130 located towards the outside corners of the die 110. In an exemplary, non-depicted embodiment, the area may include only the selected ones of the conductive bumps 130 that have an induced stress level that is above the threshold. In a particular embodiment, the density of the ILD layer such as ILD2R 236, ILD3R 238, and ILD4R 242 is advantageously increased by selectively adding reinforcing elements 240 within the patterned zone 250 of the ILD layer.

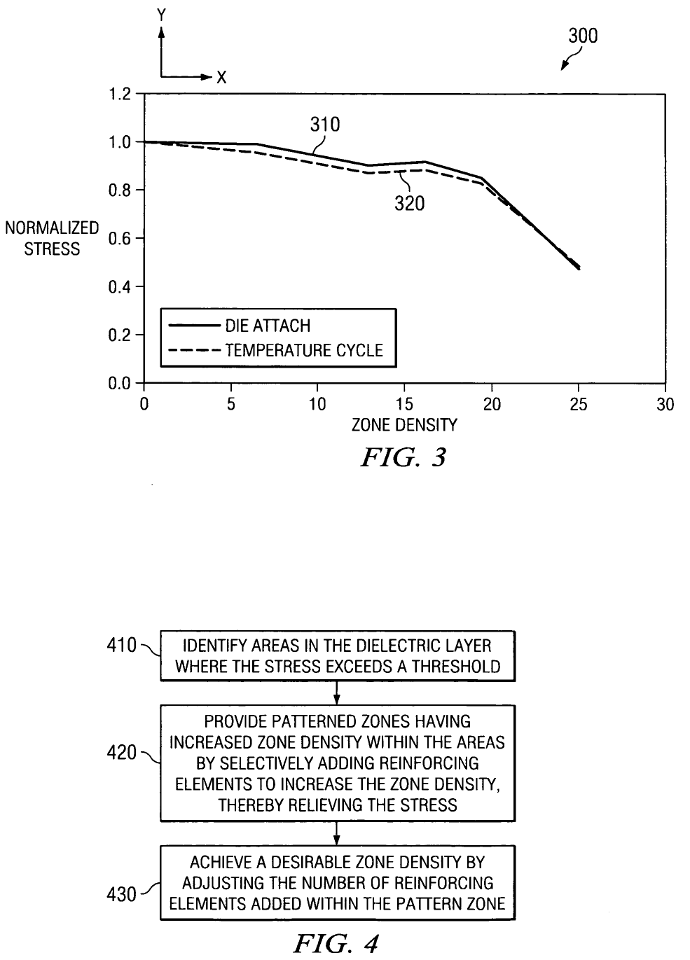

Selective and intentional addition of the reinforcing elements 240 advantageously improves the stress bearing capability of the ILD layers such as ILD2R 236, ILD3R 238, and ILD4R 242 by adjusting a zone density to reduce the induced stress within these layers to be less than the threshold. Additional details of adjusting the zone density to reduce induced stress levels are described with reference to FIGS. 2F, 2G and 3. Referring back to FIG. 2E, a desired percentage reduction in the stress level to reduce the induced stress below the threshold may vary between 5 and 95 percent. An estimated value for the desired percentage reduction in the stress level may be calculated by using modeling and simulation tools, by conducting a stress test, or a combination thereof described earlier. The reinforcing elements 240 are selectively added in reinforcement patterns that are focused to provide the maximum stress relief instead of uniformly spreading the reinforcing elements 240 throughout the ILD layer. Thus, the selective, focused approach, e.g., selecting the conductive bumps 130 that have induced stress levels above the threshold, provides targeted stress relief without substantially compromising insulation properties of the ILD.

In the depicted embodiment, the reinforcing elements 240 comprise a conductor material, which is selectable to be one of copper, gold, aluminum, tungsten, and a combination thereof. In an embodiment, the reinforcing elements are metal vias. The effective strength of the stack 202 is improved when the ILD layer (ILD2R 236, ILD3R 238, and ILD4R 242) is selectively reinforced with metal vias. The overall ILD layer acts as a composite of the two materials, e.g., the low k dielectric and the metal via, with most of the load or stress being supported by the stiffer metal vias. This has the effect of reducing the stresses in the low-k dielectric and thus reducing the chances of failure due to cohesive fracture, which may lead to an electrical failure in the metallization around this layer.

In an exemplary, non-depicted embodiment, the reinforcing elements 240 may be formed from materials other than metal. For example, the reinforcing elements 240 may be fabricated from an electrically or thermally conductive material or an insulating material provided the mechanical strength of the composite of the two materials (e.g., low k dielectric and other reinforcing material) is greater than the induced stresses. That is, provided the reinforcing material formed from materials other than metal results in stress relief in the low-k dielectric. In an embodiment, the reinforcing elements 240 comprise a dielectric material having a stress bearing capability that is greater than the stress induced by a predefined amount. In an embodiment, the dielectric material is selectable to be one of silicon oxide, silicon nitride, and silicon carbide. The materials for the reinforcing elements other than metal may also include any chemically vapor deposited (or atomic layer deposited) dielectric whose stress bearing capability exceeds that of the underlying low K material by a predefined amount. As described earlier, the reinforcing elements 240 may be arranged in the patterned zone 250 that has a shape other than a circle. For example, the reinforcing elements 240 may be arranged to from patterned zones having a cross sectional shape of an annular ring, a crescent, or a square bar. In an embodiment, each one of the cross sectional areas may vary between approximately 75% and 125% of a cross sectional area of one of the conductive bumps 130. In a particular embodiment, a ratio of the diameter of each one of the conductive bumps 130 to the diameter of each one of the reinforcing elements 240 may vary from approximately 50 to approximately 1000.

As described earlier, the zone density is an indicator of a local density of a material within a selectable zone. The zone density is a ratio of a cross sectional area of the reinforcing elements 240 included within the patterned zone 250 to an area, e.g., cross sectional area, of the patterned zone 250. In an embodiment, the zone density may also be computed as a ratio of a volume of metal contained within a volume of the patterned zone 250 to the volume of the patterned zone. The zone density computed as a ratio of areas generally assumes a uniform distribution of the volume of the metal. In applications, where distribution of the metal volume is not uniform, e.g., conically shaped vias, volume based zone density computations may be more desirable compared to area based computations. In an embodiment, the ratio may be adjustable between 0 and 95 percent. FIGS. 2F and 2G illustrate the patterned zone 250 having a zone density of 6.5% and about 25% respectively, indicating that a ratio of the area of the reinforcing elements 240 to the area of the patterned zone is 6.5% and about 25% respectively, according to an embodiment.

Referring back to FIGS. 2D and 2E, the reinforcing elements 240 are absent in an ILD region aligned between the conductive bumps 130. In a particular embodiment, even though the zone density within the patterned zone 250 may be increased, e.g., from 0 to approximately equal to 25%, the overall ILD layer density is at or below 1%, which helps to satisfy the overall die via density requirements of the process. In an embodiment, the overall ILD layer density may be increased to less than 10% by increasing the zone densities above 25%, e.g., 50% or 95%, without substantially affecting the dielectric properties. The overall ILD layer density is an indicator of an overall density of a material within the ILD layer. The ILD layer density is a ratio of an area, e.g., cross sectional area, of the reinforcing elements 240 included within the ILD layer to an area, e.g., cross sectional area, of the ILD layer.

FIG. 3 shows a graphical representation 300 of the variation of the maximum principal stress level (Y axis) induced within a semiconductor device assembly 100 having the reinforced elements 240 during a die attach process (waveform 310) and during temperature cycling (waveform 320) as a function of the zone density (X axis), according to an embodiment. The graphical representation 300 indicates a reduction in the maximum principal stress levels (normalized to 1.0 when density is 0) as the zone density (%) increases. When the zone density is approximately 25%, a reduction in the stress level of about 50% is realized compared to the stress level with 0% zone density, e.g., when no reinforcing elements are present within the ILD layer. The particular values for the zone density and the reduction in the stress level are exemplary, and may depend on the particular material properties of the materials used in the semiconductor device. As described earlier, while the graphical representation 300 is described in the context of FC mounting, those of ordinary skill in the art will appreciate that the exemplary representation is also capable of being used to describe stresses induced in semiconductor devices having other types of mounting techniques including conventional mounts having other types of electrical interconnects such as bond wires.

Adherence to particular design rules such as ‘active and/or dummy vias or metal not to exceed 10%’, which may be used in processes such as chemical mechanical planarization (CMP), may not necessarily always provide sufficient stress relief. Hence, tools and techniques described herein that first determine areas of high stress levels followed by the focused use of reinforcing elements may be desired to provide the sufficient stress relief. In the depicted embodiment, for the particular set of materials used, the reinforcing elements advantageously reduce the stress level below the threshold. That is, the approximate 50% reduction was sufficient for the material used to lower the stress level below the threshold. It is understood, that depending on the materials used in the fabrication of the semiconductor device, adjustment of the zone density above 25% may be desirable to obtain a higher and/or lower reduction in the maximum stress level to achieve a desired level that is at least below the threshold. However, as described earlier, it is desirable that the overall ILD layer density is less than 10% to retain the dielectric properties. Although the graphical representation 300 illustrates stress induced during the die attach process and during temperature cycling, it is understood that the semiconductor device assembly 100 having the reinforced elements 240 substantially reduces stress induced during other processes such as reflow, wirebond formation, die probing and similar others.

FIG. 4 is a flow chart illustrating a method for relieving stress induced within a dielectric layer of a semiconductor device, according to an embodiment. In a particular embodiment, the semiconductor device is substantially the same as the semiconductor device assembly 100 described with reference to FIGS. 1A, and 1B. At step 410, areas in the dielectric layer where the stress exceeds a threshold are identified. At step 420, patterned zones having an adjustable zone density within the areas are provided by adding reinforcing elements to increase the zone density, thereby relieving the stress.

Various steps described above may be added, omitted, combined, altered, or performed in different orders. For example, an additional step may be added to vary the density to maximize the stress relief. At step 430, the number of reinforcing elements added within the pattern zone (which determines the zone density) is adjusted to provide a desirable zone density varying from 0% to about 95%.

Several advantages are achieved by the method and system according to the illustrative embodiments presented herein. The embodiments advantageously provide for selectively adding the reinforcing elements 240 in the ILD layer of the semiconductor device assembly 100 to improve the stress bearing capability. In an exemplary semiconductor device, increasing density of the reinforcing elements 240 advantageously results in reducing the stress in the ILD layer compared to an ILD layer without the reinforcing elements. Thus, the focused approach of reinforcement provides targeted stress relief without substantially compromising insulation properties of the ILD. This advantageously enables semiconductor manufacturing facilities to improve production rates, quality and reliability.

Although illustrative embodiments have been shown and described, a wide range of modification, change and substitution is contemplated in the foregoing disclosure and in some instances, some features of the embodiments may be employed without a corresponding use of other features. Those of ordinary skill in the art will appreciate that the hardware and methods illustrated herein may vary depending on the implementation. As described earlier, while certain aspects of the present disclosure have been described in the context of flip chip mounting, those of ordinary skill in the art will appreciate that the processes disclosed are capable of being used for assembly of semiconductor devices using different types of mounting techniques including conventional mounts with wire bonding. For example, in a flip chip the stress concentration in the back end of line (BEOL) is primarily under the bumps, as bumps form the link between the die and the substrate. Similar issues exist in wirebond packages when the bond pad is probed, during wire bonding process, and during temperature cycling. Additionally, although stresses generated within the chip are described as being both mechanical and thermomechanical, additional types of stresses may also be created due to other types of loads.

The methods and systems described herein provide for an adaptable implementation. Although certain embodiments have been described using specific examples, it will be apparent to those skilled in the art that the invention is not limited to these few examples. The benefits, advantages, solutions to problems, and any element(s) that may cause any benefit, advantage, or solution to occur or become more pronounced are not to be construed as a critical, required, or an essential feature or element of the present disclosure.

The above disclosed subject matter is to be considered illustrative, and not restrictive, and the appended claims are intended to cover all such modifications, enhancements, and other embodiments, which fall within the true spirit and scope of the present disclosure. Thus, to the maximum extent allowed by law, the scope of the present disclosure is to be determined by the broadest permissible interpretation of the following claims and their equivalents, and shall not be restricted or limited by the foregoing detailed description.

What is claimed is:

1. A method for relieving stress induced within a dielectric layer of a semiconductor device, the method comprising:
identifying areas in the dielectric layer where the stress exceeds a threshold; and
providing patterned zones having an adjustable zone density within the areas, wherein the patterned zones are formed in the dielectric layer by adding reinforcing elements to increase the zone density, wherein the zone density is adjusted to lower the stress induced below the threshold.

2. The method of claim 1, wherein the areas are in parallel alignment with electrical interconnects, wherein the areas include a selected number of outer rows of the electrical interconnects, the selected number of outer rows being adjacent to a periphery of the device.

3. The method of claim 2, wherein a number of patterned zones formed in the dielectric layer corresponds to a number of electrical interconnects selected within the areas.

4. The method of claim 1, wherein the reinforcing elements comprise a conductor material, wherein the conductor material is selectable to be one of copper, gold, aluminum, tungsten, or a combination thereof.

5. The method of claim 1, wherein the reinforcing elements comprise a dielectric material having a stress bearing capability that is greater than the stress bearing capability of the dielectric layer, wherein the dielectric material is selectable to be one of silicon oxide, silicon nitride, and silicon carbide.

6. The method of claim 1, wherein the zone density is a ratio of an area of the reinforcing elements included within a patterned zone to an area of the patterned zone, wherein the ratio is adjustable between 0 and 95 percent.

7. The method of claim 1, wherein the zone density is approximately equal to 25%, thereby resulting in reducing the stress in the dielectric layer by approximately 50% compared to a dielectric layer without the reinforcing elements.

8. The method of claim 1, wherein a layer density for the dielectric layer is not greater than 1% when the zone density is approximately equal to 25%, wherein the layer density is a ratio of a volume of the reinforcing elements included within the dielectric layer to a volume of the dielectric layer.

9. The method of claim 1, wherein the reinforcing elements are metal vias, wherein a cross section of the patterned zones that includes the metal vias is substantially similar to at least one of a square, a circle, a coaxial annular ring, and a crescent.

10. The method of claim 1, wherein the stress is induced during at least one of a reflow process, a die attach process, a die probing process, a lead-free flip chip assembly process, and a temperature cycling process.

11. An integrated circuit (IC) having at least one insulating layer, the at least one insulating layer comprising:
a dielectric layer disposed over a substrate of the IC, wherein the dielectric layer includes areas where stress induced within the dielectric layer exceeds a threshold; and
patterned zones having an adjustable zone density within the areas, wherein the patterned zones are formed in the dielectric layer by adding reinforcing elements to increase the zone density, wherein the zone density is adjusted to lower the stress induced below the threshold.

12. The IC of claim 11 further comprising:
a stack of insulating layers, wherein each one of the insulating layers within the stack includes the dielectric layer having the patterned zones formed by the reinforcing elements.

13. The IC of claim 11, wherein the areas are in parallel alignment with electrical interconnects, wherein the areas include a selected number of outer rows of the electrical interconnects, the selected number of outer rows being adjacent to a periphery of the IC.

14. The IC of claim 11, wherein the reinforcing elements comprise a conductor material, wherein the conductor material is selectable to be one of copper, gold, aluminum, tungsten, or a combination thereof.

15. The IC of claim 11, wherein the reinforcing elements comprise a dielectric material having a stress bearing capability that is greater than the stress bearing capability of the dielectric layer, wherein the dielectric material is selectable to be one of silicon oxide, silicon nitride, and silicon carbide.

16. The IC of claim 11, wherein the zone density is a ratio of an area of the reinforcing elements included within a patterned zone to an area of the patterned zone, wherein the ratio is adjustable between 0 and 95 percent.

17. The IC of claim 11, wherein the zone density is approximately equal to 25%, thereby resulting in reducing the stress in the dielectric layer by approximately 50% compared to a dielectric layer without the reinforcing elements.

18. The IC of claim 11, wherein the reinforcing elements are metal vias, wherein a cross section of the patterned zones that includes the metal vias is substantially similar to at least one of a square, a circle, a coaxial annular ring, and a crescent.

19. The IC of claim 11, wherein the stress is induced during at least one of a reflow process, a die attach process, a die probing process, a lead-free flip chip assembly process, and a temperature cycling process.

20. The IC of claim 11, wherein the IC is at least one of a processor, an application specific integrated circuit (ASIC), a digital signal processor, a radio frequency chip, a memory, a microcontroller, and a system-on-a-chip or a combination thereof.
